(19) United States
(12) Patent Application Publication
(10) Pub. No.: US 2002/0122896 A1
(43) Pub. Date: Sep. 5, 2002

(54) Capillary discharge plasma apparatus and method for surface treatment using the same

(75) Inventors: Steven Kim, Harrington Park, NJ (US); Dong Woo Yu, Demarest, NJ (US); Seok-Kyun Song, Ridgefield, NJ (US); Seungdeok Kim, Palisades Park, NJ (US)

Correspondence Address: MORGAN LEWIS & BOCKIUS LLP, 1111 PENNSYLVANIA AVENUE NW, WASHINGTON, DC, 20004, US

(73) Assignee: SKION CORPORATION

(21) Appl. No.: 09/796,488

(22) Filed: Mar. 2, 2001

(51) Int. Cl. H05H 1/24; C23F 1/00; C23C 16/00; H01L 21/3065

(52) U.S. Cl. 427/569; 118/723 E; 156/345.34

(57) ABSTRACT

A plasma treatment apparatus for a workpiece includes a metal electrode, a capillary dielectric having first and second sides and coupled to the metal electrode through the first side, wherein the capillary dielectric has at least one capillary, a shield body surrounding the metal electrode and the first side of the capillary dielectric, wherein the shield body has first and second end portions, and a gas supplier providing gas to the metal electrode.

### BACKGROUND OF THE INVENTION

1. Field of the Invention

The present invention relates to a plasma discharge apparatus and method, and more particularly to an apparatus for plasma treatment using capillary discharge plasma shower. Although the present invention is suitable for a wide scope of applications, it is particularly suitable for plasma treatment of workpieces under an atmospheric pressure or high pressure, thereby providing virtually unrestricted applications regardless of the size of the workpieces.

2. Discussion of the Related Art

A plasma discharge has been widely used for treating surfaces of a variety of workpieces in many different industries. Particularly, a station for cleaning or etching electronic components, such as a printed circuit board (PCB), lead frame, microelectronic device and wafer, has been employed in electronics industries since it provides advantages over the conventional chemical cleaning apparatus. For example, the plasma process occurs in a closed system instead of in an open chemical bath. Thus, the plasma process may be less hazardous and less toxic than the conventional chemical process. One example of a related background art plasma process and apparatus was disclosed in U.S. Pat. No. 5,766,404.

Another example of the related background art was disclosed in “Surface Modification of Polytetrafluoroethylene by Ar+ Irradiation for Improved Adhesion to Other Materials”, Journal of Applied Polymer Science, pages 1913 to 1921 in 1987, in which the plasma process was applied on the surfaces of plastic workpieces in an effort to improve wetability or bonding of the workpieces.

All of the background art plasma processes, however, have to be carried out inside a treatment chamber because the background art plasma processes can only be performed under vacuum condition. Thus, when a workpiece is too big to be treated in the chamber, the background art plasma process cannot be used to treat the workpiece. As a result, the background art plasma processes are very limited in applications.

### SUMMARY OF THE INVENTION

Accordingly, the present invention is directed to an apparatus and method for plasma treatment using a capillary electrode discharge plasma shower that substantially obviates one or more of problems due to limitations and disadvantages of the related art.

Another object of the present invention is to provide an apparatus for plasma treatment using a capillary electrode discharge plasma shower which can be applied in sterilization, cleaning, etching, surface modification, or deposition of thin film under a high pressure or at an atmospheric pressure condition.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

To achieve the objects and in accordance with the purpose of the invention, as embodied and broadly described herein, a plasma treatment apparatus for a workpiece includes a first metal electrode and a second metal electrode, each receiving a potential, a capillary dielectric between the first and second metal electrodes, wherein the capillary dielectric has at least one capillary, a shield body surrounding at least a portion of said first metal electrode, wherein the shield body has first and second end portions, and a gas supplier providing a sufficient amount of working gas to the single metal electrode, thereby generating a continuous plasma shower beyond the apparatus.

In another aspect of the present invention, a plasma treatment apparatus for a workpiece includes a first metal electrode having a middle portion and first and second ends and receiving a potential, a capillary dielectric surrounding at least the middle portion and the first end of the first metal electrode and providing a plasma discharge from the middle portion and first end of the first metal electrode, and a gas supplier providing gas to the second end of the metal tube.

In another aspect of the present invention, a method of treating a workpiece using a plasma apparatus being capable of moving relative to the work piece, includes placing the workpiece in close proximity to the apparatus, wherein the apparatus includes a single metal electrode receiving a potential, a capillary dielectric having first and second sides, the first side being coupled to the single metal electrode, wherein the capillary dielectric has at least one capillary, a shield body surrounding the single metal electrode and the first side of the capillary dielectric, wherein the shield body has first and second end portions; applying a sufficient amount of working gas to the apparatus from a direction toward the work piece; applying a potential to the single metal electrode; and generating a plasma shower beyond the apparatus emitting from the capillary dielectric.

It is to be understood that both the foregoing general description and the following detailed description are exemplary and explanatory only and are not restrictive of the invention as claimed.

### BRIEF DESCRIPTION OF THE DRAWINGS

The accompanying drawings, which are incorporated in and constitute a part of this specification, illustrate several embodiments of the invention and together with the description, serve to explain the principles of the invention.

FIG. 1 is a schematic cross-sectional view illustrating an apparatus for plasma treatment using a capillary discharge plasma shower according to a first embodiment of the present invention.

FIG. 2 is a schematic cross-sectional view illustrating an apparatus for plasma treatment using the capillary discharge plasma shower according to a second embodiment of the present invention.

FIG. 3 is a schematic cross-sectional view illustrating an apparatus for plasma treatment using the CED plasma shower according to a third embodiment of the present invention.

FIG. 4 is a schematic cross-sectional view illustrating an apparatus for plasma treatment using the CED plasma shower according to a fourth embodiment of the present invention.

FIG. 5 is a schematic cross-sectional view illustrating an apparatus for plasma treatment using the CED plasma shower according to a fifth embodiment of the present invention.

FIG. 6 is a schematic cross-sectional view illustrating an apparatus for plasma treatment using the CED plasma shower according to a sixth embodiment of the present invention.

FIG. 7 is a schematic cross-sectional view illustrating an apparatus for plasma treatment using the CED plasma shower according to a seventh embodiment of the present invention.

FIGS. 8 and 9 are schematic views of various CED plasma shower heads of the present invention.

FIG. 10 is a photograph illustrating the CED plasma formed in FIG. 1.

FIG. 11 is a photograph illustrating the CED plasma formed in FIG. 2.

FIGS. 12A and 12B are photographs illustrating an example of a sterilization capability of the CED plasma treatment in the present invention.

FIG. 13A to 13C are photographs illustrating another example of the sterilization capability of the CED plasma treatment in the present invention.

FIG. 14 is a photograph illustrating an application in sterilization for a human body.

### DESCRIPTION OF THE PREFERRED EMBODIMENTS

Reference will now be made in detail to the present preferred embodiments of the invention, examples of which are illustrated in the accompanying drawings. Wherever possible, the same reference numbers will be used throughout the drawings to refer to the same or like parts.

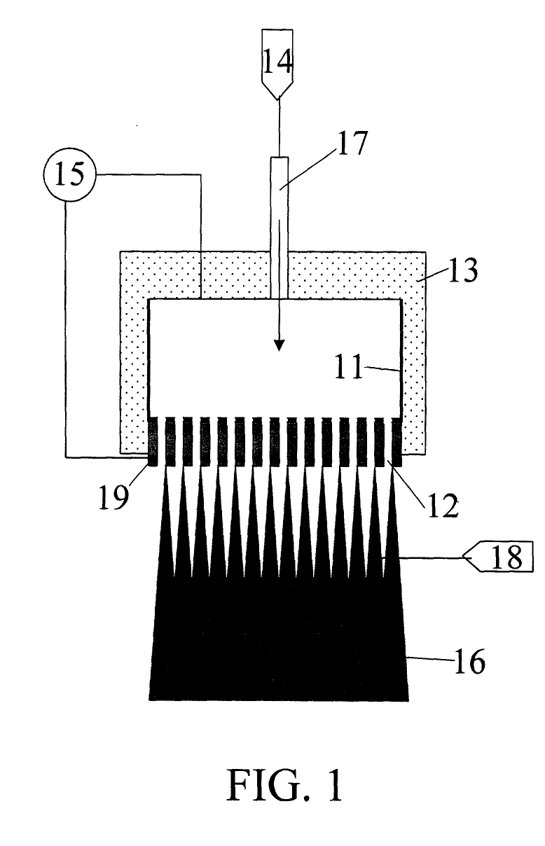

FIG. 1 is a schematic cross-sectional view illustrating an apparatus for plasma treatment using a CED plasma shower according to a first embodiment of the present invention. As shown in FIG. 1, an apparatus for plasma treatment using a CED plasma shower according to a first embodiment includes a first metal electrode 11, a capillary dielectric 12, a shield body 13, a gas supplier 14, a power supply 15 and a gas tube 17.

Specifically, the first metal electrode 11 is coupled to the power supply 15. Either a DC or a RF potential may be applied to the first metal electrode 11. In the case where the RF potential is applied, it is preferably in the range of 10 KHz to 200 MHz.

The capillary dielectric 12 has first and second sides and coupled to the first metal electrode 11 through the first side of the capillary dielectric 12. The capillary dielectric 12 has at least one capillary. For example, the number of capillaries may range from one to thousands. A thickness of the capillary dielectric 12 may be in the range of 2 mm to 300 mm. A diameter of each capillary is preferably in the range of 200 m to 30 mm.

The first metal electrode 11 can be in the form of a metal cylinder or a parallelpiped having one or more holes in the bottom surface that are substantially aligned with capillaries in the capillary dielectric 12. One side of the capillary dielectric 12 is coupled to the first metal electrode 11 inside the shield body 13 while another side of the capillary dielectric 12 is outside the shield body 13 and exposed to the workpiece W.

A glow plasma discharge device using a perforated dielectric is disclosed in U.S. Pat. No. 5,872,426, which is incorporate herein by reference.

The shield body 13 surrounds the first metal electrode 11 and the capillary dielectric 12, so that it prevents unnecessary area from generating discharge. The shield body 13 is made of a dielectric material. A grip may be formed on the shield body 13, so that a user can conveniently hold it. The gas supplied with the metal electrode 11 passes through the capillary. Since a high electric field is maintained across the capillary dielectric 12, a high density discharge beam is generated in the capillary. The gas may be a carrier gas or a reactive gas depending upon a specific application of the apparatus. For example, when the apparatus is used for thin film deposition or etching, an appropriate reactive gas is selected for a desired chemical reaction. Thus, a CED plasma discharge 16 is formed toward a workpiece (not shown).

Additionally, an auxiliary gas supplier 18 may be supplied to a space between the capillary dielectric 12 and a workpiece to be treated by plasma discharge.

The workpiece to be treated by the apparatus for plasma treatment using the CED plasma shower (discharge) may act as a counter electrode.

The gas tube 17 made of a metal or a dielectric material is further coupled to the metal electrode 11, so that gas is supplied by the gas supplier 14 through the gas tube 17. The gas can be any gas; preferably, it can be Ar, He, O₂ or air, or any mixture of these gases.

A second metal electrode 19 can be mounted on the second side of the capillary dielectric 12. Preferably, the second metal electrode 19 is completely encapsulated in the capillary dielectric to prevent arcing between the electrodes 11, 19. This second metal electrode 19 can be used to provide additional focusing of the plasma discharge 16.

The second metal electrode 19 is connected to the power supply 15 in series with the first metal electrode 11. This provides a potential difference with respect to the first metal electrode 11. It is unnecessary to connect the workpiece (not shown) to ground and workpieces made of virtually any kind of material, such as metal, ceramic, and plastic, can be treated by the apparatus of the present invention.

As an example, a photograph for the CED plasma generated according to the first embodiment of the present invention is shown in FIG. 10, wherein the apparatus has a plurality of capillary dielectric.

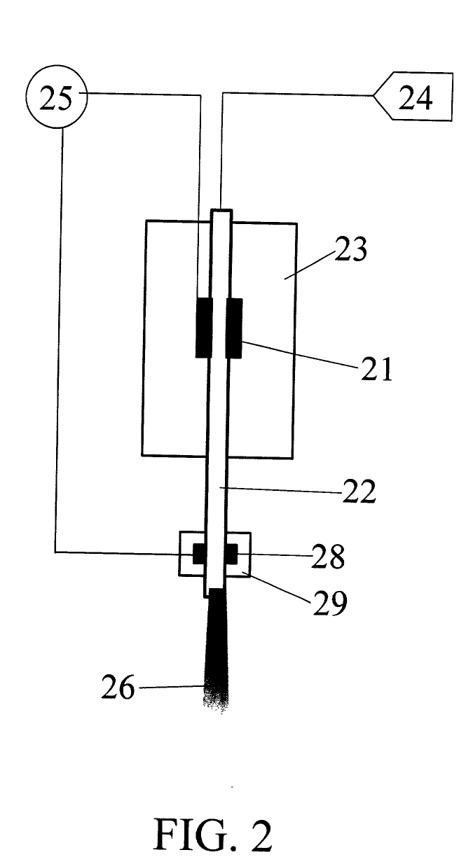

FIG. 2 is a schematic cross-sectional view illustrating an apparatus for plasma treatment using the CED plasma shower according to a second embodiment of the present invention. In FIG. 2, an apparatus for plasma treatment using the CED plasma shower according to a second embodiment of the present invention includes a first metal electrode 21, a capillary tube 22, a shield body 23, a gas supplier 24, and a power supply 25.

The first metal electrode 21 may be applied with a DC or a RF potential, and surrounds the middle portion of the capillary tube 22 which has first and second end portions. When a RF potential is applied, it is preferably in the range of 10 KHz to 200 MHz.

The first end portion of the capillary tube 22 is coupled to the gas supplier 24 while the second end portion is exposed for CED plasma shower 26. The shield body 23 covers both the first metal electrode 21 and the capillary tube 22 except for the second end portion of the capillary tube 22, so that it suppresses a discharge generation except from the second end portion of the capillary tube 22. The shield body 23 may be formed of a dielectric material. A grip may be formed on the shield body 23 for convenience. A thickness of the capillary tube 22 is preferably in the range of 2 mm to 300 mm. A diameter of the capillary tube 22 is preferably in the range of 200 m to 30 mm.

A carrier gas or a reactive gas may be supplied for the apparatus depending upon a specific application of the apparatus. The gas can be any gas; preferably, it can be Ar, He, O₂ or air, or any mixture of these gases.

A second metal electrode 28 can be mounted on the second end portion of the capillary tube 22. Preferably, the second metal electrode 28 is surrounded by the capillary tube 22 and a second shield body 29 to prevent arcing between the electrodes 21, 28. The second shield body 29 may be formed of a dielectric material. This second metal electrode 28 can be used to provide additional focusing of the plasma discharge 26.

The second metal electrode 28 is connected to the power supply 25 in series with the first metal electrode 21. This provides a potential difference with respect to the first metal electrode 21. It is unnecessary to connect the workpiece (not shown) to ground and workpieces made of virtually any kind of material, such as metal, ceramic, and plastic, can be treated by the apparatus of the present invention.

A CED plasma discharge generated from the apparatus according to the second embodiment is illustrated in FIG. 11.

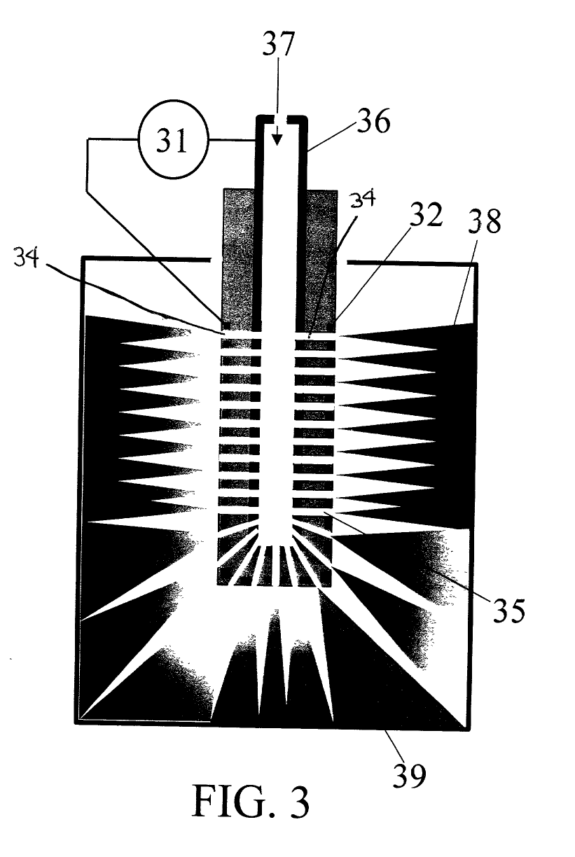

A container such as a bottle may be treated using a cylindrical shape apparatus shown in FIG. 3. A metal tube 37 has a plurality of holes 34 on its entire surface except for portions for receiving gas and for being connected to the power source. The holes 34 on the metal tube 37 match capillaries in a capillary dielectric 35. Thus, the metal tube 37 acts as a first metal electrode. The capillary dielectric 35 surrounds and is connected to the metal tube 37 as shown in FIG. 3. The capillary dielectric 35 also functions as the shield body. As a result, a CED plasma discharge is emitted from the entire surfaces towards the inner walls of the workpiece to be treated as shown in FIG. 3. Although the capillaries are parallel to one another on each side, they can be non-parallel to provide a continuous plasma shower, as shown at the lower portion of the apparatus in FIG. 3.

A second metal electrode 32 can be mounted on the capillary dielectric 35 to also surround the metal tube 37. Preferably, the second metal electrode 32 is completely encapsulated in the capillary dielectric to prevent arcing between the electrodes 32, 37. The second metal electrode 32 includes a plurality of capillaries aligned with the capillaries of the capillary dielectric 35.

The second metal electrode 32 is connected to the power source 31 in series with the metal tube 37. This provides a potential difference with respect to the metal tube 37. It is unnecessary to connect the workpiece (not shown) to ground and workpieces made of virtually any kind of material, such as metal, ceramic, and plastic, can be treated by the apparatus of the present invention.

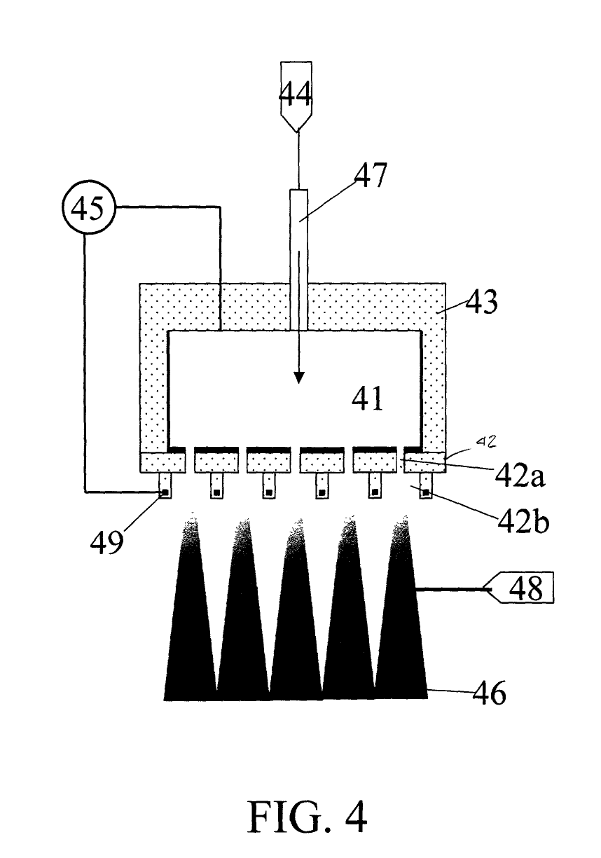

FIG. 4 illustrates a fourth embodiment of the invention of an apparatus for plasma treatment using the CED plasma shower. As shown in FIG. 4, an apparatus for plasma treatment using a CED plasma shower according to a fourth embodiment includes a first metal electrode 41, a capillary dielectric 42, a shield body 43, a gas supplier 44, a power supply 45 and a gas tube 47.

Specifically, the first metal electrode 41 is coupled to the power supply 45. Either a DC or a RF potential may be applied to the first metal electrode 41. In the case where the RF potential is applied, it is preferably in the range of 10 KHz to 200 MHz.

The capillary dielectric 42 has first and second sides and coupled to the first metal electrode 41 through the first side of the capillary dielectric 42. The capillary dielectric 42 has at least one capillary 42a. For example, the number of capillaries 42a may range from one to thousands. A thickness of the capillary dielectric 42 may be in the range of 2 mm to 300 mm. A diameter of each capillary is preferably in the range of 200 m to 30 mm.

The capillary dielectric 42 can have a portion extending from the second side. The extending portion includes openings 42b aligned with the capillaries 42a. Preferably the openings 42b are substantially larger in width than the diameter of the capillaries 42a.

The first metal electrode 41 can be in the form of a metal cylinder having one or more holes in the bottom surface that are substantially aligned with capillaries in the capillary dielectric 42. One side of the capillary dielectric 42 is coupled to the first metal electrode 11 inside the shield body 43 while another side of the capillary dielectric 42 is outside the shield body 43 and exposed to the workpiece (not shown).

The shield body 43 surrounds the first metal electrode 41 and the capillary dielectric 42, so that it prevents unnecessary area from generating discharge. The shield body 43 is made of a dielectric material. A grip may be formed on the shield body 43, so that a user can conveniently hold it. The gas supplied with the metal electrode 41 passes through the capillary. Since a high electric field is maintained across the capillary dielectric 42, a high density discharge beam is generated in the capillary. The gas may be a carrier gas or a reactive gas depending upon a specific application of the apparatus. For example, when the apparatus is used for thin film deposition or etching, an appropriate reactive gas is selected for a desired chemical reaction. Thus, a CED plasma discharge 46 is formed toward the workpiece.

Additionally, an auxiliary gas supplier 48 may be supplied to a space between the capillary dielectric 42 and the workpiece to be treated by plasma discharge.

The gas tube 47 made of a metal or a dielectric material is further coupled to the metal electrode 41, so that gas is supplied by the gas supplier 44 through the gas tube 47. The gas can be any gas; preferably, it can be Ar, He, O₂ or air, or any mixture of these gases.

A second metal electrode 49 can be mounted on the portion protruding from second side of the capillary dielectric 42. Preferably, the second metal electrode 49 is completely encapsulated in the capillary dielectric to prevent arcing between the electrodes 41, 49. This second metal electrode 49 can be used to provide additional focusing of the plasma discharge 46.

The second metal electrode 49 is connected to the power supply 45 in series with the first metal electrode 41. This provides a potential difference with respect to the first metal electrode 41. It is unnecessary to connect the workpiece (not shown) to ground and workpieces made of virtually any kind of material, such as metal, ceramic, and plastic, can be treated by the apparatus of the present invention.

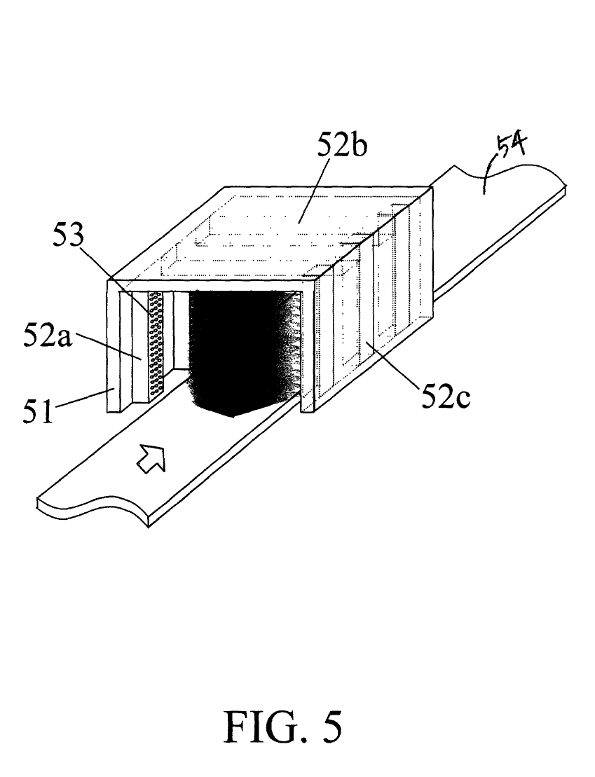

FIG. 5 illustrates a fifth embodiment of an apparatus for plasma treatment using the CED plasma shower according to the invention. The embodiment shown in FIG. 5 is a modular arrangement 51 of individual plasma treatment apparatus 52a, 52b, 52c such as the embodiments shown in any one of FIGS. 1-4. By way of example, the individual plasma treatment apparatus 52a, 52b, 52c can be in the form of a parallelpiped and constructed according to the embodiment of FIG. 1. The modular arrangement 51 can be configured in a U-shape with first individual plasma treatment apparatus 52a aligned with third individual plasma treatment apparatus 52c on opposite walls. Second individual plasma treatment apparatus 52b can be located on the wall connecting the opposite walls an alternately disposed between the first and third individual plasma treatment apparatus 52a, 52c. The modular arrangement 51 can be used on any three-dimensional structure such as elongated workpieces 54.

Alternatively, the modular arrangement can be C-shaped, L-shaped, cylindrical or any other shape. Each individual plasma treatment apparatus can be of any configuration illustrated in FIGS. 1-4 and need not be identical throughout. For example, individual plasma treatment apparatus illustrated in FIG. 1 can be combined with ones illustrated in FIG. 3.

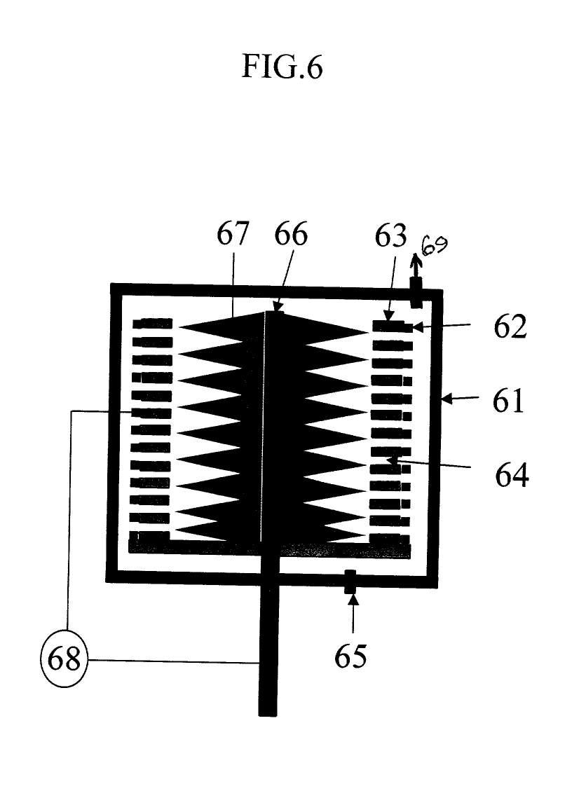

In FIG. 6, a sixth embodiment of an apparatus for plasma treatment using the CED plasma shower according to the invention includes a shield body 61, a first metal electrode 62, a dielectric capillary 63, a gas tube 65, a power supply 68 and a gas outlet 69.

Specifically, the first metal electrode 62 is coupled to the power supply 68. Either a DC or a RF potential may be applied to the first metal electrode 62. In the case where the RF potential is applied, it is preferably in the range of 10 KHz to 200 MHz.

The capillary dielectric 63 has first and second sides and coupled to the first metal electrode 62 through the first side of the capillary dielectric 63. The capillary dielectric 63 has at least one capillary. For example, the number of capillaries may range from one to thousands. A thickness of the capillary dielectric 63 may be in the range of 2 mm to 300 mm. A diameter of each capillary is preferably in the range of 200 m to 30 mm.

The first metal electrode 62 can be in the form of a metal cylinder or a parallelpiped having one or more holes that are substantially aligned with capillaries 64 in the capillary dielectric 63. One side of the capillary dielectric 63 is coupled to the first metal electrode 62 inside the shield body.

The shield body 61 surrounds the first metal electrode 62 and the capillary dielectric 63, so that it prevents unnecessary area from generating discharge. The shield body 61 is made of a dielectric material. A grip may be formed on the shield body 61, so that a user can conveniently hold it. The gas supplied with the metal electrode 62 passes through the capillary 64 and exits through the outlet 69. Since a high electric field is maintained across the capillary dielectric 63, a high density discharge beam is generated in the capillary 64. The gas may be a carrier gas or a reactive gas depending upon a specific application of the apparatus. For example, when the apparatus is used for thin film deposition or etching, an appropriate reactive gas is selected for a desired chemical reaction. Thus, a CED plasma discharge 67 is formed toward a workpiece (not shown).

The gas tube 65 made of a metal or a dielectric material is further coupled to the first metal electrode 62, so that gas is supplied by the gas supplier (not shown) through the gas tube 65. The gas can be any gas; preferably, it can be Ar, He, O₂ or air, or any mixture of these gases.

A second metal electrode 66 can be mounted on the second side of the capillary dielectric 63. In this alternate embodiment, the second metal electrode 66, preferably, is encapsulated in the capillary dielectric 63. The first metal electrode 62 surrounds the second metal electrode on at least two sides. This second metal electrode 66 can be used to provide additional focusing of the plasma discharge 67. The second metal electrode 66 can be in the form of a cylindrical rod or any other shape.

The second metal electrode 66 can be connected to the power supply 68 in series with the first metal electrode 62. This provides a potential difference with respect to the first metal electrode 62. It is unnecessary to connect the workpiece (not shown) to ground and workpieces made of virtually any kind of material, such as metal, ceramic, and plastic, can be treated by the apparatus of the present invention.

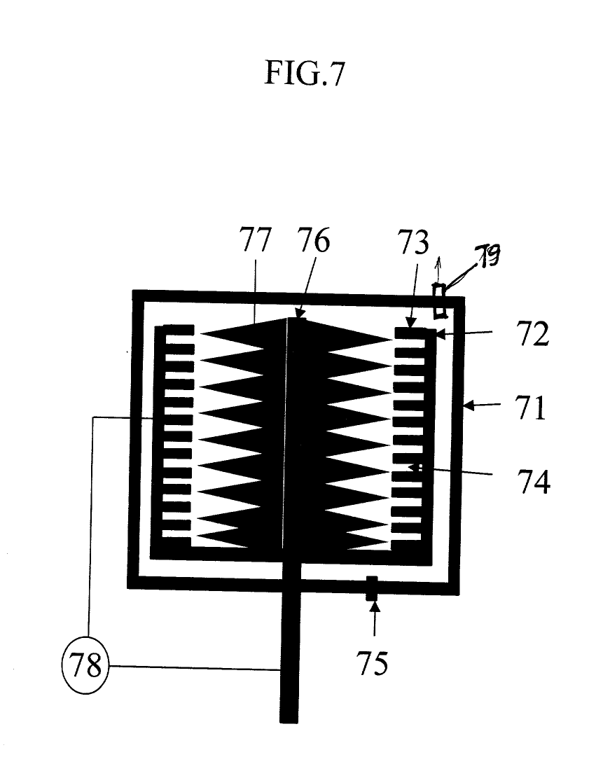

In FIG. 7, a seventh embodiment of an apparatus for plasma treatment using the CED plasma shower according to the invention includes a shield body 71, a first metal electrode 72, a dielectric capillary 73, a gas tube 75, a power supply 78 and a gas outlet 79.

Specifically, the first metal electrode 72 is coupled to the power supply 78. Either a DC or a RF potential may be applied to the first metal electrode 72. In the case where the RF potential is applied, it is preferably in the range of 10 KHz to 200 MHz.

The capillary dielectric 73 has first and second sides and coupled to the first metal electrode 72 through the first side of the capillary dielectric 73. The capillary dielectric 73 has at least one capillary. For example, the number of capillaries may range from one to thousands. A thickness of the capillary dielectric 73 may be in the range of 2 mm to 300 mm. A diameter of each capillary is preferably in the range of 200 m to 30 mm.

The first metal electrode 72 can be in the form of a metal cylinder or a parallelpiped. There are no holes formed in the first metal electrode 72 to correspond to any of the capillaries 74. One side of the capillary dielectric 73 is coupled to the first metal electrode 72 inside the shield body.

The shield body 71 surrounds the first metal electrode 72 and the capillary dielectric 73, so that it prevents unnecessary area from generating discharge. The shield body 71 is made of a dielectric material. A grip may be formed on the shield body 71, so that a user can conveniently hold it. The gas supplied with the metal electrode 72 passes through the capillary 74 and exits through the outlet 79. Since a high electric field is maintained across the capillary dielectric 73, a high density discharge beam is generated in the capillary 74. The gas may be a carrier gas or a reactive gas depending upon a specific application of the apparatus. For example, when the apparatus is used for thin film deposition or etching, an appropriate reactive gas is selected for a desired chemical reaction. Thus, a CED plasma discharge 77 is formed toward a workpiece (not shown).

The gas tube 75 made of a metal or a dielectric material is further coupled to the first metal electrode 72, so that gas is supplied by the gas supplier (not shown) through the gas tube 75. The gas can be any gas; preferably, it can be Ar, He, O₂ or air, or any mixture of these gases.

A second metal electrode 76 can be mounted on the second side of the capillary dielectric 73. In this alternate embodiment, the second metal electrode 76, preferably, is encapsulated in the capillary dielectric 73. This second metal electrode 76 can be used to provide additional focusing of the plasma discharge 77. The second metal electrode 76 can be in the form of a cylindrical rod or any other shape.

The second metal electrode 76 can be connected to the power supply 78 in series with the first metal electrode 72. This provides a potential difference with respect to the first metal electrode 72. It is unnecessary to connect the workpiece (not shown) to ground and workpieces made of virtually any kind of material, such as metal, ceramic, and plastic, can be treated by the apparatus of the present invention.

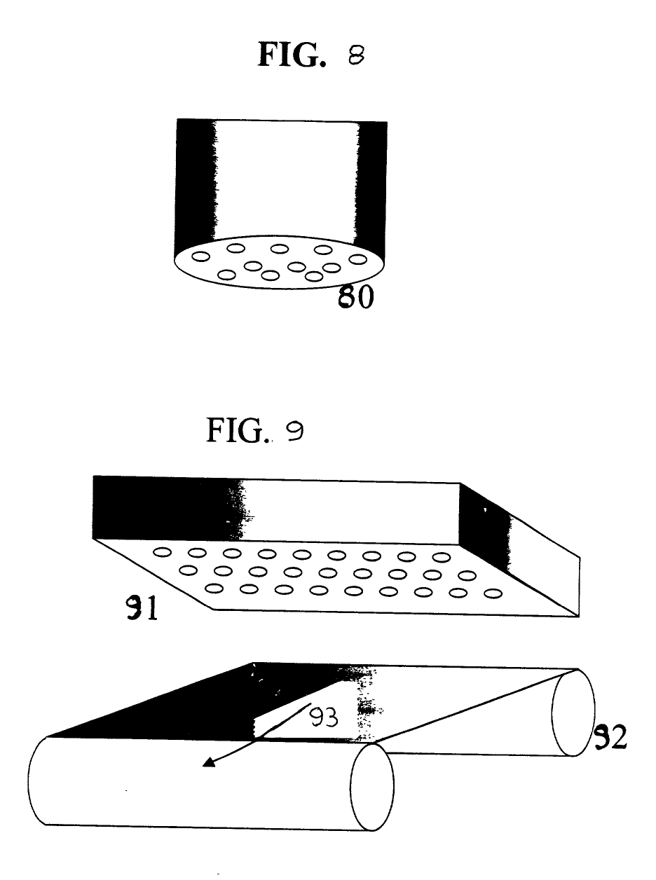

FIGS. 8 and 9 are schematic views of various shapes for an apparatus for plasma treatment using the CED plasma shower of the present invention. As shown in FIGS. 8 and 9, a shape of the apparatus for plasma treatment may vary according to a shape of the workpiece. For example, circular shape apparatus 80 shown in FIG. 8 may be appropriate for a stationary and circular workpiece. On the other hand, a workpiece 93 like a plate or a roll of sheet may be more appropriately treated with a rectangular shape apparatus 91. Normally, since this kind of workpiece may not be treated at once, the workpiece is put in a linear motion with a linearly moving mechanism 92 as shown in FIG. 9. A workpiece for a web process may also be treated by the rectangular shape apparatus 91 with a linear motion mechanism.

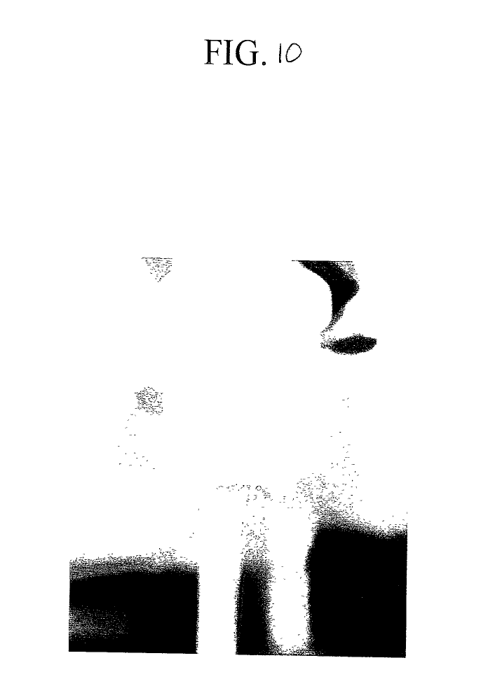

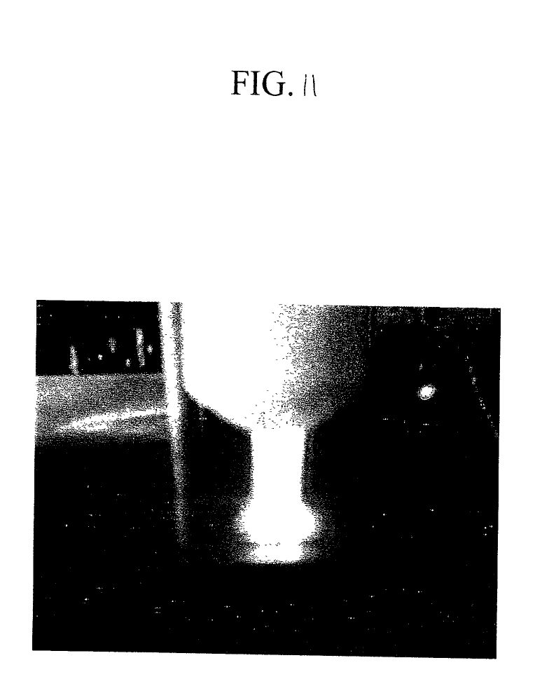

FIGS. 12A and 12B are photographs illustrating an example of a sterilization capability of the CED plasma treatment in the present invention. As shown therein, FIG. 12A illustrates that the first sample treated with the CED plasma shower of the present invention contains no bacteria growth. Conversely, a microbial growth is observed in the second sample treated with the conventional AC barrier type plasma, as shown in FIG. 12B. Thus, the treatment by the CED plasma shower of the present invention is much more effective than the conventional AC barrier type plasma treatment in sterilization.

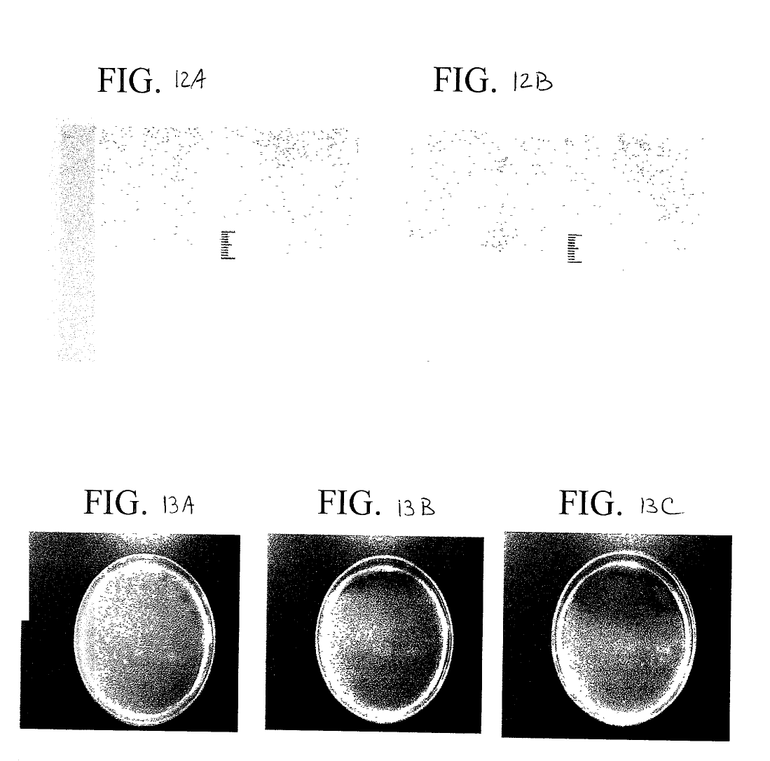

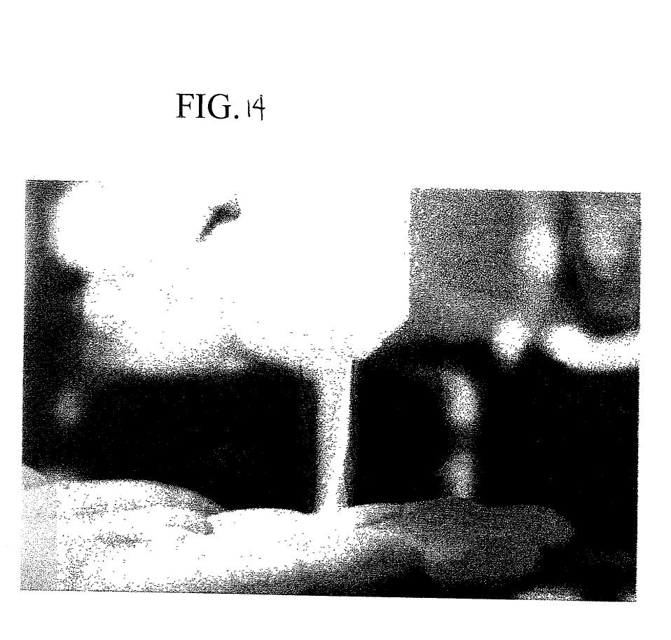

FIGS. 13A to 13C are photographs illustrating another example of the sterilization capability of the CED plasma treatment in the present invention. In this example, each of three identical soil samples is suspended in water and filtered to remove debris. A spore stain of the samples is smeared and fixed to a microscope slide in order to confirm that endospores are present in the samples. Thereafter, the first sample is treated with the CED plasma while the second sample is treated with the conventional AC barrier type plasma each for 6 minutes. The third sample is not treated by plasma at all. All samples are collected onto a cotton swab and soaked with sterile distilled water. The cotton swab was plunged into 1 ml of sterile distilled water. The swab was then streaked onto LB agar plates (yeast extract and typtone), and incubated at 37° C. for 18 hours. Then each sample is observed. The first sample treated with the CED plasma shower shows no lawn of microbial growth and only a single bacteria cell, as shown in FIG. 13A. Unlike the first sample, the second and third samples contain a partial or a full lawn of microbial growth, as shown in FIGS. 13B and 13C, respectfully.

FIG. 14 is a photograph illustrating an application in sterilization for a human body. Since the plasma generated by the CED plasma shower of the present invention is non-thermal, it may be directly applied to a human body for sterilization and cleaning under the circumstances.

As described above, the apparatus for plasma treatment using capillary electrode discharge plasma shower has the following advantages over the conventional plasma treatment apparatus.

The CED shower of the present invention may be used for plasma treatment of workpieces under an atmospheric pressure or high pressure. Thus, it provides virtually unrestricted applications regardless of the size of the workpieces.

Moreover, in a sterilization process, the treatment by the CED plasma shower of the present invention is much more effective than the conventional AC barrier type plasma treatment.

It will be apparent to those skilled in the art that various modifications and variations can be made in the method and apparatus for treatment using capillary electrode discharge plasma shower of the present invention without departing from the scope or spirit of the invention. Thus, it is intended that the present invention cover the modifications and variations of the invention provided they come within the scope of the appended claims and their equivalents.

What is claimed is:

1. A plasma apparatus for treating a workpiece placed in close proximity to the apparatus capable of moving relative to the workpiece, comprising:
a first metal electrode and a second metal electrode, each receiving a potential;
a capillary dielectric between the first and second metal electrodes and surrounds the second metal electrode, wherein the capillary dielectric has at least one capillary;
a shield body surrounding at least a portion of said first metal electrode, wherein the shield body has first and second end portions; and
a gas supplier providing a sufficient amount of working gas to the single metal electrode, thereby generating a continuous plasma shower beyond the apparatus.

2. The apparatus according to claim 1, further comprising a power supply providing a RF potential to the metal electrode in the range of 10 KHz to 200 MHz.

3. The apparatus according to claim 1, wherein the first end portion of the shield body has a cavity for carrying the gas.

4. The apparatus according to claim 1, wherein the second end portion has a circular shape or polygonal shape.

5. The apparatus according to claim 1, wherein the first end portion of the shield body includes a grip to be held by a user.

6. The apparatus according to claim 1, wherein the shield body includes a dielectric material.

7. The apparatus according to claim 1, wherein the potential includes either a DC or a RF potential.

8. The apparatus according to claim 1, wherein the workpiece acts as a counter electrode.

9. The apparatus according to claim 1, wherein the workpiece includes one of metal, ceramic, plastic and living organism.

10. The apparatus according to claim 1, wherein the workpiece is grounded with respect to the first and second metal electrodes.

11. The apparatus according to claim 1, wherein the shield body suppresses a plasma discharge except from the second side of the capillary dielectric.

12. The apparatus according to claim 1, wherein the capillary dielectric has a thickness in the range of 2 mm to 300 mm.

13. The apparatus according to claim 1, wherein the at least one capillary has a diameter in the range of 200 m to 30 mm.

14. The apparatus according to claim 1, further comprising an auxiliary gas supplier providing auxiliary gas into a space between the second side of the capillary dielectric and the workpiece.

15. The apparatus according to claim 1, wherein the first metal electrode has a cylindrical shape.

16. The apparatus according to claim 1, wherein the first metal electrode has a parallelpiped shape.

17. The apparatus according to claim 1, wherein the first and second metal electrodes, the capillary dielectric and the shield body form a module; and
a plurality of the modules arranged to define a channel through the workpiece may be passed.

18. The apparatus according to claim 17, wherein the channel is U-shaped.

19. The apparatus according to claim 17, wherein each module of the plurality of modules on one side of the channel are alternately disposed with each module of the plurality of modules on an adjacent side of the channel.

20. The apparatus according to claim 1, wherein the first metal electrode has at least one hole in a surface coupled to the first side of the capillary dielectric.

21. The apparatus according to claim 20, wherein the at least one hole is substantially aligned with the at least one capillary of the capillary dielectric.

22. The apparatus according to claim 21, wherein the second metal electrode has at least one hole in a surface coupled to the second side of the capillary dielectric.

23. The apparatus according to claim 22, wherein the at least one hole of the second metal electrode is substantially aligned with the at least one capillary of the capillary dielectric.

24. The apparatus according to claim 22, wherein the at least one hole of the second metal electrode is substantially greater in width than the at least one capillary.

25. The apparatus according to claim 1, further comprising a gas tube coupled to the first end portion of the shield body.

26. The apparatus according to claim 1, wherein the first metal electrode has a hollow for accommodating the gas.

27. The apparatus according to claim 1, wherein the capillary dielectric includes having first and second sides, the first side being coupled to the first metal electrode and the second side being coupled to said second metal electrode.

28. The apparatus according to claim 1, wherein the capillary dielectric includes a tube having first and second end portions surrounded by the first and second metal electrodes, respectively.

29. The apparatus according to claim 28, wherein the second metal electrode is located at the second end portion of the capillary tube.

30. The apparatus according to claim 29 further comprising a second shield body surrounding the second metal electrode.

31. The apparatus according to claim 28, wherein the shield body has a first side having a circular shape or a polygonal shape and facing the workpiece.

32. The apparatus according to claim 28, wherein the gas is supplied into the capillary tube through the first end portion of the capillary tube.

33. The apparatus according to claim 1, wherein the first metal electrode is mounted on the capillary dielectric, and the first metal electrode and the capillary dielectric surround the second metal.

34. The apparatus according to claim 33, wherein the capillary dielectric has a cylindrical shape.

35. The apparatus according to claim 33, wherein the first metal electrode includes at least one capillary.

36. The apparatus according to claim 35, wherein the number of the capillaries of the first metal electrode is the same as that of the hollow capillary dielectric body.

37. The apparatus according to claim 1, wherein the dielectric body surrounds the first metal electrode and has a cylindrical shape consisting of first, second, and third surfaces.

38. The apparatus according to claim 1 wherein the capillary dielectric encapsulates the second metal electrode.

39. A plasma apparatus for treating a workpiece placed in close proximity to the apparatus and for being capable of moving relative to the workpiece, comprising:
a single metal electrode having a middle portion and first and second ends and receiving a potential;
a capillary dielectric surrounding at least the middle portion and the first end of the first metal electrode, the capillary dielectric providing a plasma discharge from the middle portion and first end of the first metal electrode; and a second metal electrode surrounding at least the middle portion and the first end of the first metal electrode, wherein the second metal electrode is encapsulated in the capillary dielectric;
a gas supplier providing a sufficient amount of working gas to the second end of the metal electrode, thereby generating a continuous plasma shower beyond the apparatus.

40. The apparatus according to claim 39, wherein the capillary dielectric includes a first plurality of capillaries extending in a first direction, a second plurality of capillaries extending in a second direction and a third plurality of capillaries wherein each capillary of the third plurality of capillaries extends in a respective direction different from the first and second directions.

41. The apparatus according to claim 40, wherein the first direction is perpendicular to the second direction.

42. The apparatus of claim 40, wherein the metal electrode is cylindrical and includes a radial direction and an axial direction, the first direction is the radial direction and the second direction is the axial direction.

43. A method of treating a workpiece using a plasma apparatus being capable of moving relative to the work piece, comprising:
placing the workpiece in close proximity to the apparatus, wherein the apparatus includes,
a first metal electrode and a second metal electrode;
a capillary dielectric between the first and second metal electrodes and surrounds the second metal electrode, wherein the capillary dielectric has at least one capillary;
a shield body surrounding at least a portion of said first metal electrode, wherein the shield body has first and second end portions;
applying a sufficient amount of working gas to the apparatus from a direction toward the work piece;
applying a potential to each of the first and second metal electrodes; and
generating a plasma shower beyond the apparatus emitting from the capillary dielectric.
